(19) United States
(12) Patent Application Publication
(10) Pub. No.: US 2019/0371982 A1
(43) Pub. Date: Dec. 5, 2019

(54) A process for fabricating a substrate-less package and application thereof

(71) Applicant: Jiangsu New Cloud China Photoelectric Technology Co., LTD, RuDong County (CN)

(72) Inventor: LI-CHEN LIN, New Taipei City (TW)

(21) Appl. No.: 16/486,637

(22) PCT Filed: Feb. 17, 2017
(86) PCT No.: PCT/CN2017/000181

§ 371 Date: Aug. 16, 2019

(51) Int. Cl. H01L 33/56; H01L 33/00; H01L 25/075; B29C 43/18; B29C 33/68

(52) U.S. Cl. CPC H01L 33/56; H01L 33/0079; H01L 25/0753; B29K 2083/00; B29C 33/68; H01L 2933/005; B29C 2043/182; B29C 43/18

(57) ABSTRACT

A process for fabricating a substrate-less package and application thereof are disclosure. The process comprises steps described as following: provide a first release film; place a plurality of substance on the first release film; cover the substance with a chemical; provide a mold has a groove; place a second release film on surface of the groove; perform a molding process to have the chemical and the substance form a package; and then remove the mold, the first release film and the second release film to obtain the substrate-less package.

### TECHNICAL FIELD OF THE INVENTION

The present invention relates to a process for fabricating a substrate-less package. Particularly, a process for fabricating a substrate-less light emitting diode is provided.

### BACKGROUND OF THE INVENTION

Typically, substrates are used to support chips, emitting-light iodides, or circuits. However, traditional package with substrates is not able to satisfy a thinning-size design or micro-size design of illuminating devices and/or electronic products.

Patent No 1387067 discloses a process for making chips package, the process uses strong acids, such as HF, to etch the substrates.

In illumination industry, traditional LED package is poor for heat dissipation and/or lamp appearance design. Hence, there is a need to solve the aforementioned problems. Accordingly, a process for fabricating a substrate-less package is urgent demand in illumination industry and/or electronic industry.

### SUMMARY OF THE INVENTION

In one aspect, the present invention provides a process for fabricating a substrate-less package.

The invented process for fabricating a substrate-less package comprises following steps.

Provide a first release film; place a plurality of substance on the first release film, wherein the substance comprises a chip, a wafer, a luminous body, a semi-conductor, a passive component, an electrode or a circuit; cover the substance with a chemical; provide a mold has a groove; place a second release film on surface of the groove; perform a molding process to have the chemical and the substance form a package between the first release film, the second release film and the mold; and remove the mold, the first release film and the second release film to obtain a substrate-less package.

In one embodiment, the first release film comprises a fluorine resin film, an acrylate resin film, a silicone film or its combination.

In one embodiment, the chemical comprises a silicone, an epoxy resin, a luminous resin or a conductive resin.

In one embodiment, the second release film comprises a fluorine-resin film, an acrylate resin film, a silicone film or their combinations.

In one embodiment, the molding process is compression molding and operating temperature of the compression molding is 60-200° C.

In one embodiment, the compression molding is operated at a pressure range of 4˜12 tons.

In one embodiment, the substrate-less package comprises a substrate-less chip package, a substrate-less wafer package, a substrate-less luminous body package, a substrate-less semi-conductor package, a substrate-less passive component package, a substrate-less electrode package or a substrate-less circuit package.

In one preferred embodiment, the luminous body is a light-emitting diode (LED).

In another aspect, the present invention provides a process for fabricating a substrate-less light-emitting diode package.

The invented process for fabricating a substrate-less light-emitting diode package comprises following steps.

Provide a first release film; place a plurality of light-emitting diodes on the first release film; cover the light-emitting diode with a chemical; provide a mold has a groove; place a second release film on surface of the groove; perform a molding process to have the chemical and the light-emitting diode form a package or a semi-product between the first release film, the second release film and the mold; and remove the mold, the first release film and the second release film to obtain a substrate-less light-emitting diode package.

In one embodiment, the first release film comprises a fluorine resin film, an acrylate resin film, a silicone film or their combinations.

In one embodiment, the chemical comprises a silicone, an epoxy resin, or an conductive resin.

In one embodiment, the second release film comprises a fluorine-resin film, an acrylate-resin film, a silicone film or their combinations.

In one embodiment, the molding process is compression molding and operating temperature of the compression molding is 60-200° C.

In one embodiment, the compression molding is operated at a pressure range of 4˜12 tons.

In one embodiment, the substrate-less light-emitting diode package has a luminous intensity larger than 150 lumens.

In one embodiment, the substrate-less light-emitting diode package is applied to change luminous angle of a body.

In one embodiment, the substrate-less light-emitting diode package has a luminous angle between 5 and 180 degree.

According to the invention, the process has the following advantages: (1). Release films are used to temporarily support substances during a packing or encapsulating process. After the packing or encapsulating process is finished, the release films are easily remove from the substances for obtaining a substrate-less substance package. The invented process does not use any hazardous or toxic chemicals, so the invented process is an environmental-friendly process when compared to traditional packing process involve etching steps. (2). Different mold groove size and/or appearance design is able to make different size and/or appearance substrate-less substance package. As a result, the invented process is able to make various substrate-less substance package and very flexible to apply in many industries. (3). A substrate-less light-emitting diode package fabricated by the invented process is able to enhance 20% or above luminous intensity and change or control luminous angle of body by different size and/or appearance design. The aforementioned advantages of the invention are not achieved by current packing process involve etching steps.

### BRIEF DESCRIPTION OF THE DRAWINGS

FIG. 1 is a schematic diagram of the representative example of the first embodiment; and

FIG. 2 is a process flow diagram of the representative example of the first embodiment.

### BRIEF DESCRIPTION OF THE PREFERRED EMBODIMENTS

What is probed into the invention is a process for fabricating a substrate-less package and its application. Detail descriptions of the steps will be provided in the following in order to make the invention thoroughly understood. Obviously, the application of the invention is not confined to specific details familiar to those who are skilled in the art. On the other hand, the common steps, structures and elements that are known to everyone are not described in details to avoid unnecessary limits of the invention. Some preferred embodiments of the present invention will now be described in greater detail in the following. However, it should be recognized that the present invention can be practiced in a wide range of other embodiments besides those explicitly described, that is, this invention can also be applied extensively to other embodiments, and the scope of the present invention is expressly not limited except as specified in the accompanying claims

In the first embodiment, the present invention provides a process for fabricating a substrate-less package.

The invented process for fabricating a substrate-less package comprises following steps.

Provide a first release film; place a plurality of substance on the first release film, wherein the substance comprises a chip, a wafer, a luminous body, a semi-conductor, a passive component, an electrode or a circuit; cover the substance with a chemical; provide a mold has a groove; place a second release film on surface of the groove; perform a molding process to have the chemical and the substance form a package between the first release film, the second release film and the mold; and remove the mold, the first release film and the second release film to obtain the substrate-less package.

In one embodiment, the first release film comprises a fluorine resin film, an acrylate resin film, a silicone film or its combination.

In one embodiment, the chemical comprises a silicone, an epoxy resin, a luminous resin or a conductive resin.

In one embodiment, the second release film comprises a fluorine-resin film, an acrylate resin film, a silicone film or their combinations.

In one embodiment, the molding process is compression molding and operating temperature of the compression molding is 60-200′C.

In one embodiment, the compression molding is operated at a pressure range of 4˜12 tons.

In one embodiment, the substrate-less package comprises a substrate-less chip package, a substrate-less wafer package, a substrate-less luminous body package, a substrate-less semi-conductor package, a substrate-less passive component package, a substrate-less electrode package or a substrate-less circuit package.

In one preferred embodiment, the luminous body is a light-emitting diode (LED).

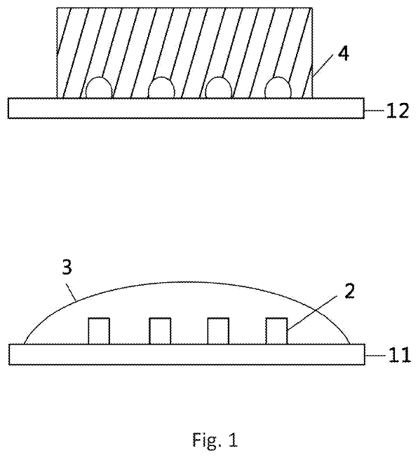

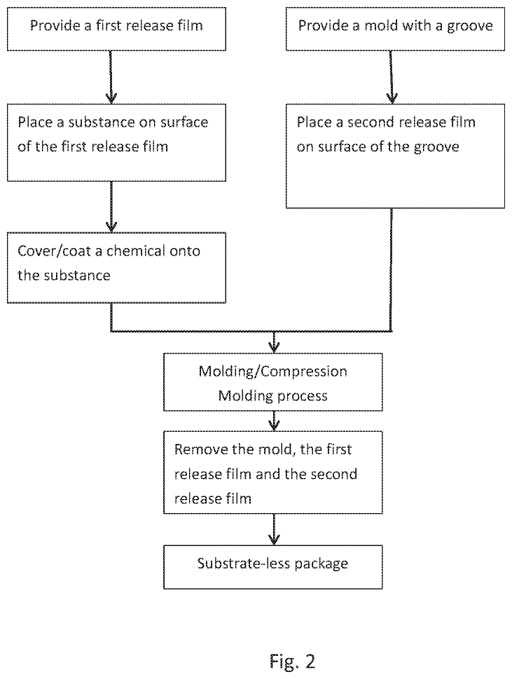

In one representative example of the first embodiment, the detail steps are described according to FIG. 1 and FIG. 2. Firstly, provide a first release film 11. The first release film 11 is place on a plane object. Place a substance 2 on the first release film 11. The substance 2 is a pack or encapsulated target and comprises a chip, a wafer, a luminous body, a semi-conductor, a passive component, an electrode or a circuit. Cover or coat a chemical 3 onto the substance 2. The chemical comprises a silicone, an epoxy resin, a luminous resin or a conductive resin. Provide a mold 4 with a various size and/or appearance groove. Place or put a second release film 12 onto surface of the groove. Combine the first release film 11 has the substance 2 covered or coated by the chemical 3 onto the mold 4 has the second release film 12 on its groove surface. Perform a compression molding to have the substance 2 to be pack or encapsulated with the chemical for forming a package or semi-finished product. The operation condition of the compression molding is 60° C. on vacuum, and the compression pressure is 5 tons. Finally, after remove the mold 4, the first release film 11 and the second release film 12 from the semi-finished product, the invented substrate-less substance package is obtained.

In a second embodiment, the present invention discloses a process for fabricating a substrate-less light-emitting diode package. The process comprises following steps.

Provide a first release film; place a plurality of light-emitting diode on the first release film; cover the light-emitting diode with a chemical; provide a mold has a groove; place a second release film on surface of the groove; perform a molding process to have the chemical and the light-emitting diode form a package between the first release film, the second release film and the mold; and remove the mold, the first release film and the second release film to obtain the substrate-less light-emitting diode package.

In one embodiment, the first release film comprises a fluorine resin film, an acrylate resin film, a silicone film or their combinations.

In one embodiment, the chemical comprises a silicone, an epoxy resin, or an conductive resin.

In one embodiment, the second release film comprises a fluorine-resin film, an acrylate-resin film, a silicone film or their combinations.

In one embodiment, the molding process is compression molding and operating temperature of the compression molding is 60-200° C.

In one embodiment, the compression molding is operated at a pressure range of 4˜12 tons.

In one embodiment, the substrate-less light-emitting diode package has a luminous intensity larger than 150 lumens.

In one embodiment, the substrate-less light-emitting diode package is applied to change luminous angle of a body.

In one embodiment, the substrate-less light-emitting diode package has a luminous angle between 5 and 180 degree.

In one representative example of the second embodiment, the detail steps are described as following. Firstly, provide a first release film 11. The first release film 11 is place on a plane object. Place a light emitting diode (LED) on the first release film 11. Cover or coat a chemical 3 onto the substance 2. The chemical comprises a silicone, an epoxy resin or a conductive resin. Provide a mold 4 with a various size and/or appearance groove. Place or put a second release film 12 onto surface of the groove. Combine the first release film 11 has the LED covered or coated by the chemical 3 onto the mold 4 has the second release film 12 on its groove surface. Perform a compression molding to have the LED to be pack or encapsulated with the chemical for forming a semi-finished product. The operation condition of the compression molding is 50° C. on vacuum, and the compression pressure is 8 tons. Finally, after remove the mold 4, the first release film 11 and the second release film 12 from the semi-finished product, the invented substrate-less LED package is obtained.

One substrate-less LED package fabricated according to the process described in the aforementioned representative example has following characters. Size of the substrate-less LED package is 2.8 mm*2.8 mm and the thickness is 1.5 mm. Luminous angle of the substrate-less LED package is 30 degree. Luminous intensity of the substrate-less LED package enhances 30% when compared to traditional LED package and is 156 lumens.

Accordingly, the present invention discloses a process for fabricating a substrate-less package as well as a process for fabricating a substrate-less light emitting diode. One inventive step of the invention is used release films as a temporarily support for substances during a packing or encapsulating process. After the packing or encapsulating process is finished, the release films are easily remove from the substances for obtaining a substrate-less substance package. Therefore, the invented process does not use any hazardous or toxic chemicals, so the invented process is an environmental-friendly process when compared to traditional packing process involve etching steps. Moreover, different mold groove size and/or appearance design is able to apply in the invented process for making various substrate-less substance package. Thirdly, the substrate-less light-emitting diode package fabricated by the invented process is able to enhance 20% or above luminous intensity and change or control luminous angle of body by different size and/or appearance design.

Obviously many modifications and variations are possible in light of the above teachings. It is therefore to be understood that within the scope of the appended claims the present invention can be practiced otherwise than as specifically described herein. Although specific embodiments have been illustrated and described herein, it is obvious to those skilled in the art that many modifications of the present invention may be made without departing from what is intended to be limited solely by the appended claims.

What is claimed is:

1. A process for fabricating a substrate-less package, the process comprising:
(1) providing a first release film;
(2) placing a plurality of substance on the first release film, wherein the substance comprises a chip, a wafer, a luminous body, a semi-conductor, a passive component, an electrode or a circuit;
(3) covering the substance with a chemical;
(4) providing a mold has a groove;
(5) placing a second release film on surface of the groove;
(6) performing a molding process to have the chemical and the substance form a package; and
(7) removing the mold, the first release film and the second release film to obtain the substrate-less package.

2. The process of claim 1, wherein the first release film comprises a fluorine resin film, an acrylate resin film, a silicone film or its combination.

3. The process of claim 1, wherein the chemical comprises a silicone, an epoxy resin, a luminous resin or a conductive resin.

4. The process of claim 1, wherein the second release film comprises a fluorine-resin film, an acrylate resin film, a silicone film or their combinations.

5. The process of claim 1, wherein the molding process is compression molding and operating temperature of the compression molding is 60-200′C.

6. The process of claim 5, wherein the compression molding is operated at a pressure range of 4˜12 24 tons.

7. The process of claim 1, wherein the substrate-less package comprises a substrate-less chip package, a substrate-less wafer package, a substrate-less luminous body package, a substrate-less semi-conductor package, a substrate-less passive component package, a substrate-less electrode package or a substrate-less circuit package.

8. The process of claim 1, wherein the luminous body is a light-emitting diode (LED).

9. A process for fabricating a substrate-less light-emitting diode package, comprises:
(1) providing a first release film;
(2) placing a plurality of light-emitting diode on the first release film;
(3) covering the light-emitting diode with a chemical;
(4) providing a mold has a groove;
(5) placing a second release film on surface of the groove;
(6) performing a molding process to have the chemical and the light-emitting diode form a package; and
(7) removing the mold, the first release film and the second release film to obtain the substrate-less light-emitting diode package.

10. The process of claim 9, wherein the first release film comprises a fluorine resin film, an acrylate resin film, a silicone film or their combinations.

11. The process of claim 9, wherein the chemical comprises a silicone, an epoxy resin, or an conductive resin.

12. The process of claim 9, wherein the second release film comprises a fluorine-resin film, an acrylate-resin film, a silicone film or their combinations.

13. The process of claim 9, wherein the molding process is compression molding and operating temperature of the compression molding is 60-200′C.

14. The process of claim 13, wherein the compression molding is operated at a pressure range of 4˜12 tons.

15. The process of claim 9, wherein the substrate-less light-emitting diode package has a luminous intensity larger than 150 lumen.

16. The process of claim 9, wherein the substrate-less light-emitting diode package is applied to change luminous angle of a body.

17. The process of claim 9, wherein the substrate-less light-emitting diode package has a luminous angle between 5 and 180 degree.
